(19) United States
(12) Patent Application Publication
(10) Pub. No.: US 2026/0363108 A1
(43) Pub. Date: Nov. 12, 2026

(54) Methods and Devices for Compensating Differential-to-Common Mode Noise in Electronic Packages

(71) Applicant: PARADE TECHNOLOGIES, LTD., San Jose, CA (US)

(72) Inventors: HongWei Wu, Zhubei City (TW); ChihHung Tang, Zhubei City (TW); ChaoChing Huang, Zhubei City (TW)

(21) Appl. No.: 19/204,395

(22) Filed: May 9, 2025

(51) Int. Cl. H10W 70/65; H10W 70/05; H10W 90/00

(52) U.S. Cl. CPC H10W 70/65; H10W 70/05; H10W 90/754

(57) ABSTRACT

This application is directed to compensating common mode noise of differential signals in electronic packages. An electronic device includes a device substrate configured to support an electronic chip, two wire pads coupled on a surface of the device substrate, a first power plane coupled to the device substrate, and a second power plane coupled to the device substrate. The two wire pads are configured to receive two signal wires for carrying a differential signal. The first power plane is configured to provide a first supply voltage, and the first power plane further includes a cutout opening and a conductive contact path starting from an edge of the cutout opening, extending within the cutout opening, and terminating at a first power pad located inside the cutout opening. The second power plane is configured to provide a second supply voltage.

### TECHNICAL FIELD

This application relates to electronic technology, and in particular electronic components, electronic packages, electronic devices, electronic systems, and methods for compensating common mode noise of differential signals.

### BACKGROUND

Differential signals are commonly used in high-speed digital and analog systems, such as on printed circuit boards (PCBs), because of their robustness to noise and improved signal integrity. Differential signals consist of two complementary voltage waveforms transmitted along a differential pair of conductors. Rather than referencing each signal to a common ground, a receiver senses the voltage difference between the two lines, allowing for improved immunity to external noise. In PCBs and other electronic packages, these differential pairs are routed closely together to ensure consistent coupling, matched lengths, and controlled impedance (e.g., 100 ohms) to maintain signal integrity across high-speed connections. Although differential signaling minimizes noise susceptibility, some noise concerns remain. Differential-mode noise, arising from mismatched lengths, uneven trace geometry, or nearby signal interference (crosstalk), can degrade performance. Despite not referencing a traditional ground for signal transmission, differential signals still rely on power and ground planes for any common-mode currents. Common-mode noise may come up if external interference couples unequally into traces of the differential signals, e.g., from the power and ground planes. It would be beneficial to have an effective common-mode noise controlling mechanism.

### SUMMARY

In accordance with some embodiments of this application is at least a realization that a differential signal relies on stable power and ground planes within a PCB to support active components and provide low-impedance return paths for any common-mode currents. Proper layout design, including tight trace coupling and consistent ground plane coverage, is crucial for controlling common-mode and differential-mode noise in differential signaling. For example, a pair of bond wires are coupled to signal input/output (I/O) bond pads in an electronic package to transfer a differential signal. The signal I/O bond pads are formed on a semiconductor die, and may have an unbalanced reference bond pad pinout (e.g., with a first power bond pad on one side and a second power bond pad on the other side), thereby leading to asymmetric return paths of the signal I/O bond pads. Specifically, in some situations, two signal I/O bond pads of the differential signal correspond to a reference ground bond wire and a reference power bond wire, respectively. When the reference ground bond wire has a faster signal return than the reference power bond wire, the differential signal is unbalanced with an increase in differential-to-common mode noise, thereby causing increased electromagnetic interference (EMI) and signal integrity issues.

Various embodiments of this application are directed to integrated circuits, electronic components, electronic devices, electronic systems, and methods of configuring a power plane to compensate common mode noise of differential signals. A conductive contact path is created on the power plane to electrically couple the power plane to a power pad associated with a differential signal. Stated another way, the conductive contact path corresponds to a transmission line applied as a compensation circuit configured to reduce differential-to-common mode noise caused by a skew between positive and negative signals of a differential signal port. The compensation circuit may be represented by parasitic capacitance and parasitic inductance integrated with the transmission line. A width and a length of the transmission line are adjusted to control parasitic capacitance, inductance, and resistance, thereby allowing a reference power wire to be coupled to the power plane properly to reduce differential-to-common mode noise in the differential signal. In some embodiments, the reference power wire, the power pad, and the power plane are associated with a power supply (e.g., VDD, VSS, ground).

In one aspect of this application, an electronic device includes a device substrate configured to support an electronic chip, two wire pads coupled on a surface of the device substrate, a first power plane coupled to the device substrate, and a second power plane coupled to the device substrate. The two wire pads are configured to receive two signal wires for carrying a differential signal. The first power plane is configured to provide a first supply voltage, and the first power plane further includes a cutout opening and a conductive contact path starting from an edge of the cutout opening, extending within the cutout opening, and terminating at a first power pad located inside the cutout opening. The second power plane is configured to provide a second supply voltage. In some embodiments, the first power plane is electrically coupled to a ground.

In some embodiments, the cutout opening has a shape corresponding to one of a group of shapes consisting of a rectangular shape, a circular shape, a triangular shape, an “L” shape, and an “T” shape.

In another aspect, a method is implemented for providing an electronic device. The method includes providing a device substrate configured to support an electronic chip and providing two wire pads coupled on a surface of the device substrate. The two wire pads configured to receive two signal wires for carrying a differential signal. The method further includes providing a first power plane coupled to the device substrate. The first power plane is configured to provide a first supply voltage, and the first power plane further includes a cutout opening and a conductive contact path starting from an edge of the cutout opening, extending within the cutout opening, and terminating at a first power pad located inside the cutout opening. The method further includes providing a second power plane coupled to the device substrate, and the second power plane is configured to provide a second supply voltage.

In some embodiments, the differential signal corresponds to two power supplies coupled to two power planes via two distinct power wires. A physical length of at least one of the two distinct power wires is adjusted to balance the two distinct power wires. Alternatively, in some embodiments, an inductance of one of the two power planes is adjusted to control the differential-to-common noise of the differential signal.

These illustrative embodiments are mentioned not to limit or define the disclosure, but to provide examples to aid understanding thereof. Additional embodiments are discussed in the Detailed Description, and further description is provided there.

### BRIEF DESCRIPTION OF DRAWINGS

The disclosed embodiments have other advantages and features, which will be more readily apparent from the detailed description, the appended claims, and the accompanying figures (or drawings). A brief introduction of the figures is below.

FIG. 1 is a perspective view of an example electronic device having a compensation structure formed on a first power plane, in accordance with some embodiments.

FIG. 2A is a perspective view of an electronic device that does not include any compensation structure on a first power plane, in accordance with some embodiments, and FIG. 2B is a perspective view of another example electronic device having a compensation structure formed on a first power plane, in accordance with some embodiments.

FIG. 3A is a graph comparing example differential-to-common mode losses of electronic devices and shown in FIGS. 2A and 2B, in accordance with some embodiments, and FIG. 3B is a graph comparing example reflection losses of electronic devices shown in FIGS. 2A and 2B, in accordance with some embodiments.

FIG. 4 illustrates an example compensation structure and a schematic diagram of an equivalent compensation circuit, in accordance with some embodiments.

FIGS. 5A and 5B are a perspective see-through view and a side view of an example electronic device having a compensation structure, in accordance with some embodiments.

FIG. 6A is an expanded view of an example compensation structure applied in an electronic device shown in FIG. 5A, in accordance with some embodiments, and FIG. 6B is a schematic view of an example equivalent compensation circuit of a compensation structure of an electronic device, in accordance with some embodiments.

FIG. 7A is a graph comparing example differential mode insertion losses (SDD21) associated with a compensated electronic device and an uncompensated electronic device, in accordance with some embodiments.

FIG. 7B is a graph comparing example differential mode reflection losses (SDD11) associated with a compensated electronic device and an uncompensated electronic device, in accordance with some embodiments.

FIG. 7C is a graph comparing example differential-to-common mode losses (SCD21) associated with a compensated electronic device and an uncompensated electronic device, in accordance with some embodiments.

FIG. 8A is a top view of another example compensation structure applied in an electronic device, in accordance with some embodiments, and FIG. 8B is a graph comparing example differential-to-common mode losses (SCD21) associated with a compensated electronic device using the compensation structure shown in FIG. 8A and an uncompensated electronic device, in accordance with some embodiments.

FIG. 9A is a schematic view of an example compensation circuit including a plurality of distributed parasitic components, in accordance with some embodiments.

FIGS. 9B-9D are top views of three example compensation structures that are represented by respective compensation circuits, in accordance with some embodiments.

FIG. 10 is a flow diagram of an example method for providing an electronic device, in accordance with some embodiments.

Like reference numerals refer to corresponding parts throughout the several views of the drawings.

### DETAILED DESCRIPTION

The figures and the following description relate to embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

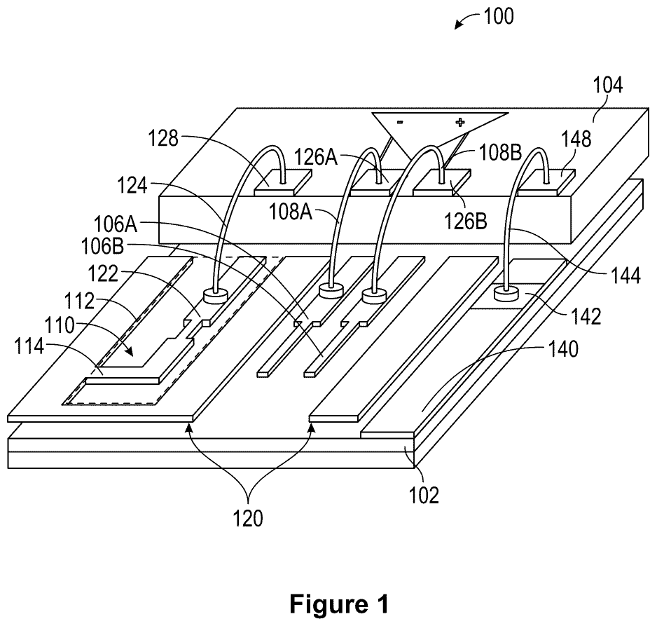

FIG. 1 is a perspective view of an example electronic device 100 having a compensation structure 110 formed on a first power plane 120, in accordance with some embodiments. The electronic device 100 includes a device substrate 102 configured to support an electronic chip 104 and two wire pads 106A and 106B coupled on a surface of the device substrate 102. The two wire pads 106A and 106B are configured to receive two signal wires 108A and 108B for carrying a differential signal. The electronic device 100 further includes the first power plane 120 coupled to the device substrate 102 and a second power plane 140 coupled to the device substrate 102. The first power plane 120 is configured to provide a first supply voltage, and the second power plane 140 is configured to provide a second supply voltage. In an example, the first power plane 120 is a ground plane electrically coupled to a ground of the electronic device 100. The first power plane 120 further includes a cutout opening 112 and a conductive contact path 114 starting from an edge of the cutout opening 112, extending within the cutout opening 112, and terminating at a first power pad 122 located inside the cutout opening 112. Stated another way, the cutout opening 112 and the conductive contact path 114 form the compensation structure 110 of the first power plane 120.

In some embodiments, the first power pad 122 is configured to receive a first power wire 124 for carrying the first supply voltage. The second power plane 140 includes or is coupled to a second power pad area 142 configured to receive a second power wire 144 for carrying the second supply voltage. An impedance measured at the first power pad 122 of the first power plane 120 is configured to match an impedance measured at the second power pad area 142 of the second power plane 140. In some embodiments, the two impedances measured at the first power pad 122 and the second power pad area 142 match each other when a difference of the two impedance is less than a threshold difference (e.g., 5% or 20% of one of the two impedances).

In some embodiments, the electronic device 100 includes the electronic chip 104, and the electronic chip 104 is disposed on top of the device substrate 102. The electronic chip 104 further includes two device power pads 128 and 148 electrically coupled to the first power plane 120 and the second power plane 140 using two distinct power wires 124 and 144, respectively. The electronic chip 104 is configured to generate the differential signal, e.g., with reference to the first supply voltage and the second supply voltage. The first supply voltage is lower than the second supply voltage.

In some embodiments, the electronic chip 104 is disposed on top of the device substrate 102, and configured to generate the differential signal and output the differential signal via a pair of signal pads 126A and 126B. The two signal wires 108A and 108B are configured to transfer the differential signal from the pair of signal pads 126A and 126B to the two wire pads 106A and 106B.

In some embodiments, the first power pad 122 has a predefined location that is aligned with locations of the two wire pads 106A and 106B. Further, in some embodiments, the first power pad 122, the two wire pads 106A and 106B, and the second power pad area 142 are aligned with one another. The electronic chip 104 includes a row of conductive pads (e.g., pads 128, 126A, 126B, and 148) that may be coupled to the pads 122, 106A, 106B, and 122 via respective wires 124, 108A, 108B, and 144, respectively. When the pads 122, 106A, 106B, and 142 are aligned, the respective wires 124, 108A, 108B, and 144 match one another (i.e., have substantially equal lengths and substantially equal impedances). In some embodiments, two ends of each of the wires 124, 108A, 108B, and 144 are joined to respective conductive pads using ultrasonic bonding or welding.

In some embodiments, the first power pad 122 and the two wire pads 106A and 106B are exposed on the surface of the device substrate 102. The first power plane 120 is embedded within the device substrate 102 jointly with the conductive contact path 114. In some embodiments, the conductive contact path 114 is exposed on the surface of the device substrate 102 jointly with the first power pad 122 and the two wire pads 106A and 106B. A remaining portion of the first power plane 120 distinct from the conductive contact path 114 is embedded in the device substrate 102. In some embodiments, the first power plane 120 is exposed on the surface of the device substrate 102 jointly with the first power pad 122, the conductive contact path 114, and the two wire pads 106A and 106B. In some embodiments, the first power pad 122 and the second power plane 140 are on the same conductive layer of the device substrate 102. In some embodiments, the first power pad 122 and the second power plane 140 are on two different conductive layers of the device substrate 102.

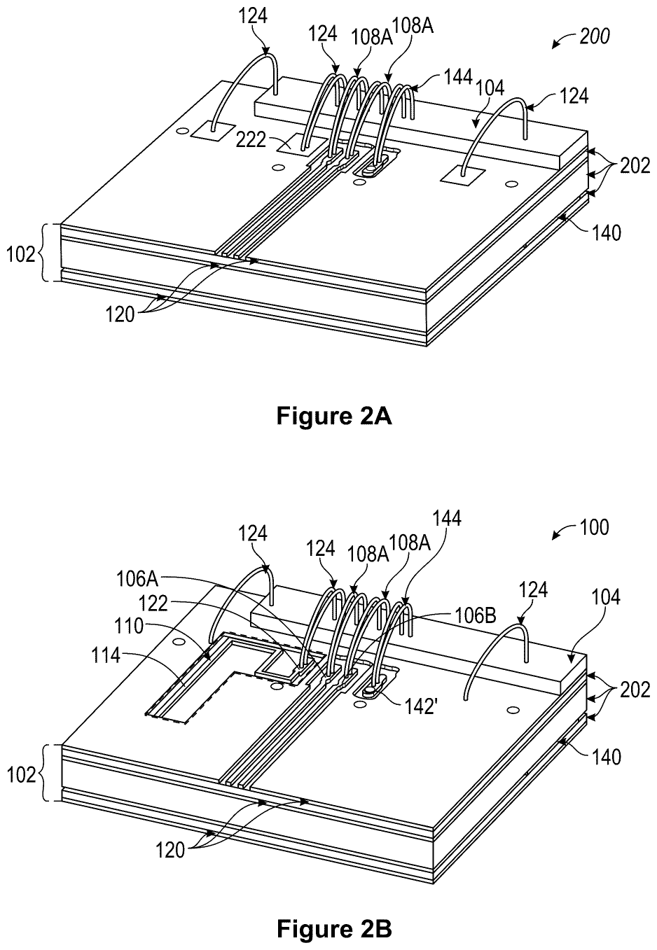

FIG. 2A is a perspective view of an electronic device 200 that does not include any compensation structure 110 on a first power plane 120, in accordance with some embodiments, and FIG. 2B is a perspective view of another example electronic device 100 having a compensation structure 110 formed on a first power plane 120, in accordance with some embodiments. Each electronic device 100 or 200 includes a device substrate 102 configured to support an electronic chip 104, two wire pads 106A and 106B coupled on a surface of the device substrate 102, a first power plane 120, and a second power plane 140. In an example, the first power plane 120 is a ground plane electrically coupled to a ground of the electronic device 100 or 200. Referring to FIG. 2B, in some embodiments, the first power plane 120 further includes a cutout opening 112 and a conductive contact path 114 starting from an edge of the cutout opening 112, extending within the cutout opening 112, and terminating at a first power pad 122 located inside the cutout opening 112. The cutout opening 112 and the conductive contact path 114 form the compensation structure 110 of the first power plane 120.

Referring to FIG. 2A, in some embodiments, the electronic device 200 does not include any compensation structure 110 formed on the first power plane 120. The first power plane 120 includes an alternative power pad area 222 configured to receive a first power wire 144 for carrying a first supply voltage. In some embodiments, the electronic device 200 includes a plurality of alternative power pad areas 222. The electronic chip 104 includes a plurality of device power pads 128 distributed on different locations. The plurality of device power pads 128 of the electronic chip 104 are electrically coupled to the plurality of alternative power pad areas 222 of the first power plane 120 using a plurality of first power wires 124.

In some embodiments, the electronic device 200 that does not include any compensation structure 110 has a skew issue with the differential signal transferred at a differential signal port (e.g., corresponding to signal pads 126A and 126B, signal wires 108A and 108B, and wire pads 106A and 106B). For example, the differential signal has a larger impedance with respect to the second power plane 140 compared with the first power plane 120, thereby incurring a higher level of differential-to-common mode noise. Conversely, in some embodiments (FIG. 2B), the compensation structure 110 of the electronic device 100 includes the cutout opening 112 and the conductive contact path 114. The conductive contact path 114 is coupled between the first power pad 122 and a body of the first power plane 120, and configured to compensate a mismatch between the impedances associated with the first power plane 120 and the second power plane 140. In this example, the cutout opening 112 has an “L” shape, and the conductive contact path 114 has a flipped “S” shape.

In some embodiments, the electronic device 100 or 200 includes a plurality of first power planes 120 (e.g., 3 power planes 120 in FIGS. 2A and 2B). In some embodiments, the second power plane 140 is arranged in a different conductive layer of the device substrate 102 from the first power pad 122. Every two adjacent planes of the first power plane(s) 120 and the second power plane 140 are electrically isolated from one another by a respective non-conductive layer 202 (e.g., made of dielectric material). In some embodiments, the first power plane 120 includes one or more openings in which the two wire pads 106A and 106B and a second power pad 142′. The second power pad 142′ is electrically coupled to the second power pad area 142 of the second power plane 140 configured to receive a second power wire 144 for carrying the second supply voltage.

In some embodiments (FIG. 2B), the cutout opening 112 is surrounded by the first power plane 120. Alternatively, in some embodiments (FIG. 1), the cutout opening 112 is formed on, and has an open edge overlapping, an edge of the first power plane 120.

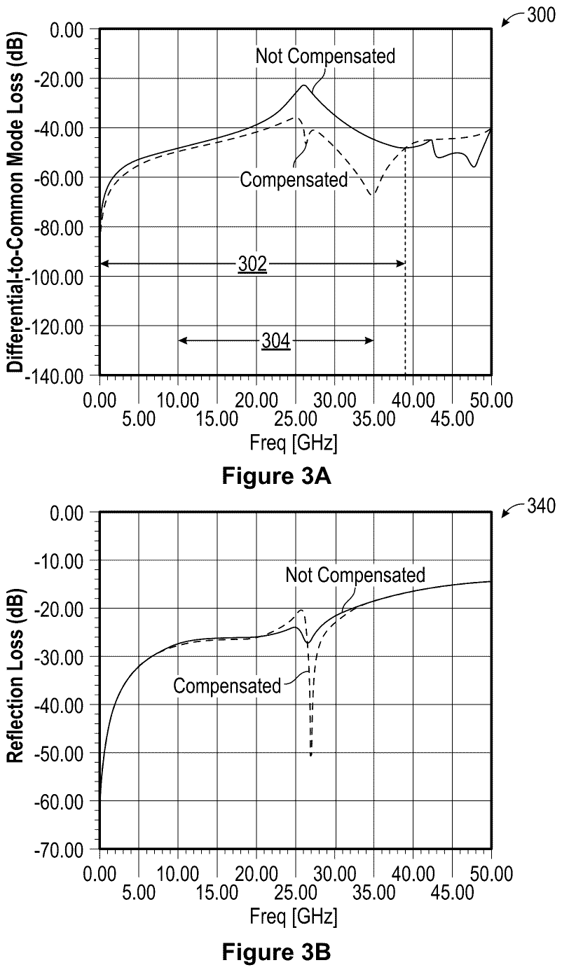

FIG. 3A is a graph 300 comparing example differential-to-common mode losses of electronic devices 100 and 200 shown in FIGS. 2A and 2B, in accordance with some embodiments, and FIG. 3B is a graph 340 comparing example reflection losses of electronic devices 100 and 200 shown in FIGS. 2A and 2B, in accordance with some embodiments. Referring to FIG. 3A, the differential-to-common mode loss (labeled “Compensated”) of the electronic device 100 having a compensation structure 110 is lower than the differential-to-common mode loss (labeled “Not Compensated”) of the electronic device 200 that is not compensated in a first frequency range 302 (e.g., 0-39 GHz). The first frequency range 302 includes an operating bandwidth range 304 where the differential signal is generated and transferred. The compensation structure 110 may improve the differential-to-common mode loss of the differential signal carried by the two signal wires 108A and 108B in the operating bandwidth range 304.

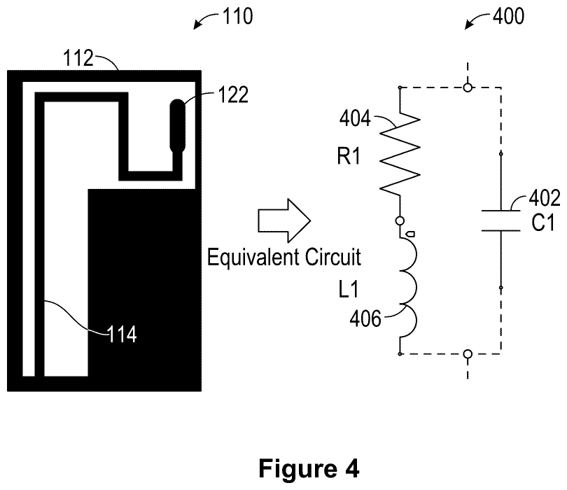

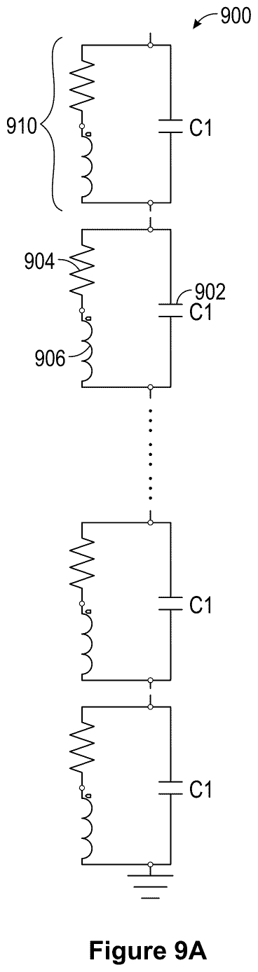

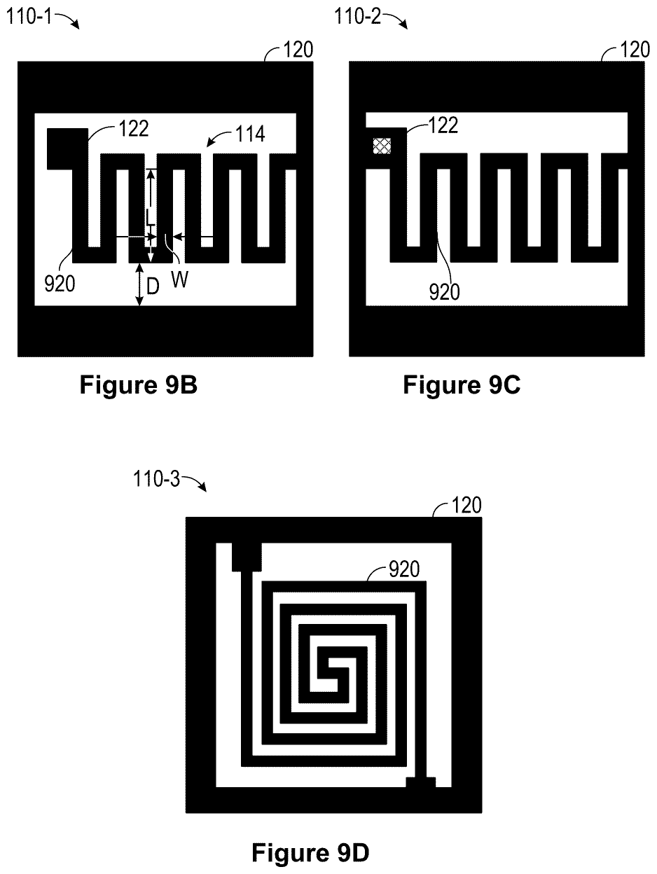

FIG. 4 illustrates an example compensation structure 110 and a schematic diagram of an equivalent compensation circuit 400, in accordance with some embodiments. The compensation structure 110 of the electronic device 100 includes the cutout opening 112 and the conductive contact path 114. The conductive contact path 114 is coupled between the first power pad 122 and a body of the first power plane 120, and configured to compensate a mismatch between impedances associated with the first power plane 120 and a second power plane 140. In this example, the cutout opening 112 has a flipped “L” shape, and the conductive contact path 114 has a flipped “S” shape. The compensation circuit 400 includes a parasitic capacitor 402, a parasitic resistor 404, and a parasitic inductor 406 corresponding to the conductive contact path 114. The conductive contact path 114 includes a transmission trace having a length and a width, and is configured to control the parasitic capacitor 402, the parasitic resistor 404, and the parasitic inductor 406, thereby compensating the mismatch between the impedances associated with the power planes 120 and 140. In some embodiments, the conductive contact path 114 includes a plurality of segments each of which has a length, a width, and a path position. More details on configuring the plurality of segments of the conductive contact path 114 are explained below with reference to FIGS. 9A-9D.

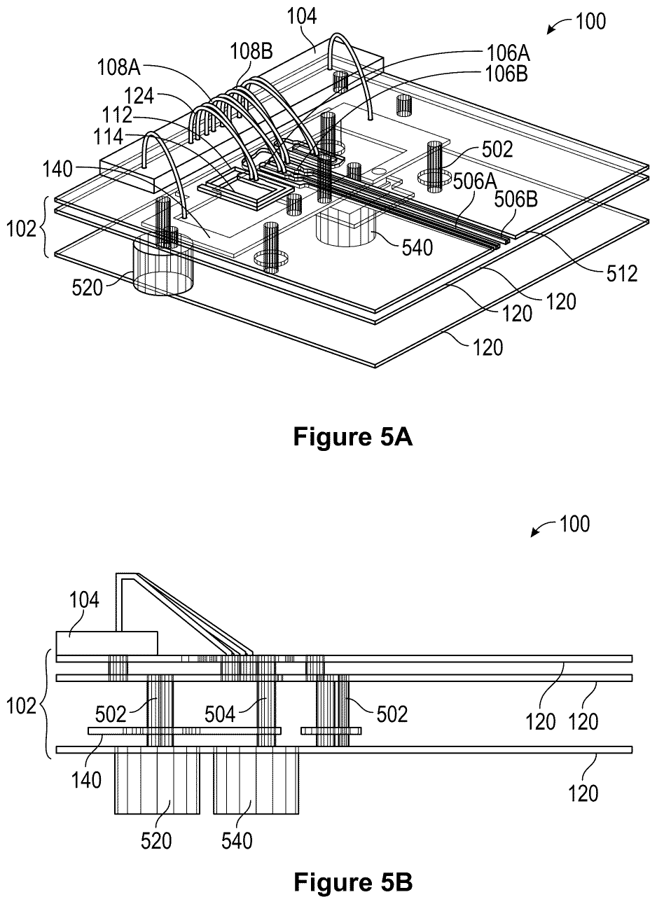

FIGS. 5A and 5B are a perspective see-through view and a side view of an example electronic device 100 having a compensation structure 110, in accordance with some embodiments. The electronic device 100 includes a device substrate 102 configured to support an electronic chip 104, two wire pads 106A and 106B coupled on a front surface of the device substrate 102, a plurality of first power planes 120, and a second power plane 140. For example, the plurality of first power planes 120 are ground planes electrically coupled to a ground of the electronic device 100. In some embodiments, the device substrate 102 includes a printed circuit board (PCB), and the plurality of first power planes 120 include a top power plane 120T, a middle power plane 120M, and a bottom power plane 120B. Every two adjacent first power planes 120 (e.g., planes 120T and 120B) are electrically coupled via first conductive vias 502 and electrically isolated by a respective non-conductive layer (not shown). The plurality of first power planes 120 are electrically coupled to a first contact structure 520 located on a rear surface of the device substrate 102, which is opposite to the front surface of the device substrate 102 where the electronic chip 104 is mounted and the two wire pads 106A and 106B are exposed.

In some embodiments, the second power plane 140 is located on the same material layer as, and configured to extend to, one of the plurality of power planes 120 (e.g., 120T, 120M, or 120B). Alternatively, referring to FIG. 5B, in some embodiments, the second power plane 140 is located between two of the plurality of power planes 120. The second power plane 140 includes or is coupled via a second conductive via 504 to a second power pad area 142 configured to receive a second power wire 144 for carrying the second supply voltage. The second power plane 140 is electrically coupled to a second contact structure 540 located on the rear surface of the device substrate 102. In some embodiments, each second conductive via 504 passes through each of one or more respective first power planes 120 by way of a respective hole, and is electrically isolated from the one or more respective first power planes 120. In some embodiments, a subset of first conductive vias 502 passes through the second power plane 140 by way of a respective hole, and is electrically isolated from the second power plane 140.

Referring to FIG. 5A, the first power plane 120 further includes a cutout opening 112 and a conductive contact path 114. The conductive contact path 114 starts from an edge of the cutout opening 112, extends within the cutout opening 112, and terminates at a first power pad 122 located inside the cutout opening 112. The cutout opening 112 and the conductive contact path 114 form the compensation structure 110 of the first power plane 120. The two wire pads 106A and 106B are configured to receive two signal wires 108A and 108B for carrying a differential signal. In some embodiments, the two wire pads 106A and 106B are electrically coupled to two signal traces 506A and 506B, which are configured to carry the differential signal on the device substrate 102. Further, in some embodiments, the signal traces 506A and 506B and the first power plane 120 are formed on the same conductive layer. The first power plane 120 includes a second cutout opening 512 in which the two signal traces 506A and 506B are routed. Alternatively, in some embodiments not shown, the signal traces 506A and 506B and the first power plane 120 are formed on two distinct conductive layers.

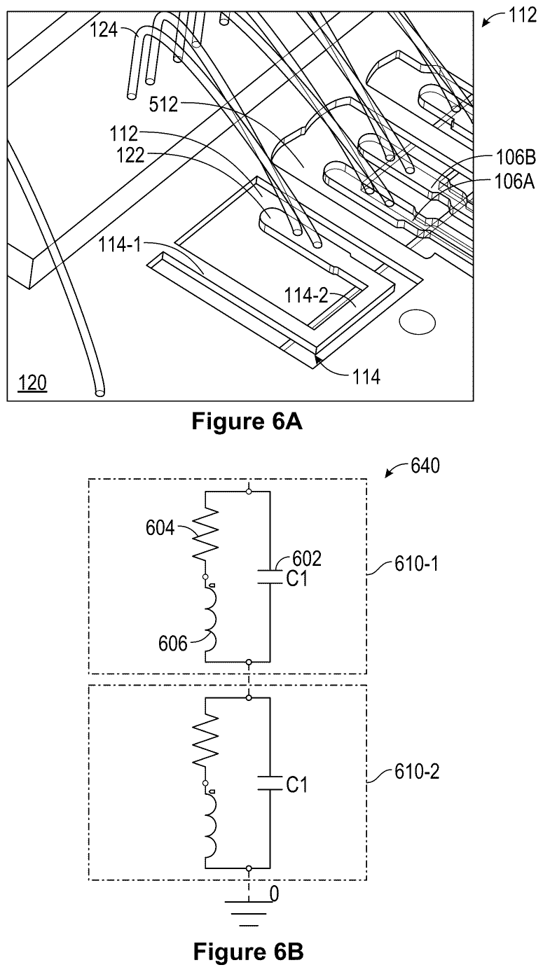

FIG. 6A is an expanded view of an example compensation structure 110 applied in the electronic device 100 shown in FIG. 5A, in accordance with some embodiments, and FIG. 6B is a schematic view of an example equivalent compensation circuit 640 of the compensation structure 110 of the electronic device 100, in accordance with some embodiments. The cutout opening 112 has a rectangular shape, and the conductive contact path 114 has an “L” shape. In some embodiments, the compensation structure 110 acts as a band-pass filter. Further, referring to FIGS. 6A and 6B, the compensation structure 110 acts as a second-order band-pass filter. Stated another way, the equivalent compensation circuit 640 includes the second-order band-pass filter, and may be represented as two parasitic components 610-1 and 610-2. Each parasitic component 610-1 or 610-2 includes a parasitic capacitor 602, a parasitic resistor 604, and a parasitic inductor 606. In some embodiments, the parasitic inductor 606 integrates the parasitic resistor 604. In some embodiments, the compensation circuit 640 has an operating bandwidth range further including a peak frequency associated with a differential-to-common mode loss (e.g., in FIG. 3A). The equivalent compensation circuit 640 is configured to improve the differential-to-common mode loss of the differential signal transferred between the electronic chip 104 and the device substrate 102.

In some embodiments, the conductive contact path 114 has an “L” shape that further includes two segments 114-1 and 114-2. Each segment 114-1 or 114-2 has a width W, a length L, a position in the conductive contact path 114, and distances D from edges of the cutout opening 112, and is configured to determine the parasitic capacitor 602, the parasitic resistor 604, and the parasitic inductor 606 of a respective parasitic component 610-1 or 610-2.

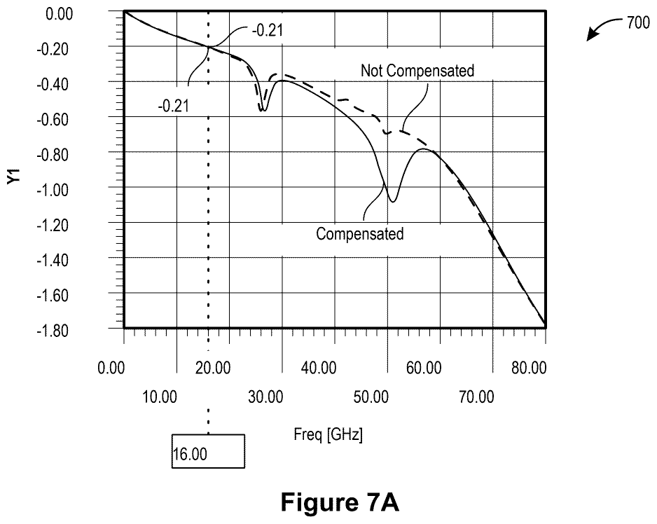

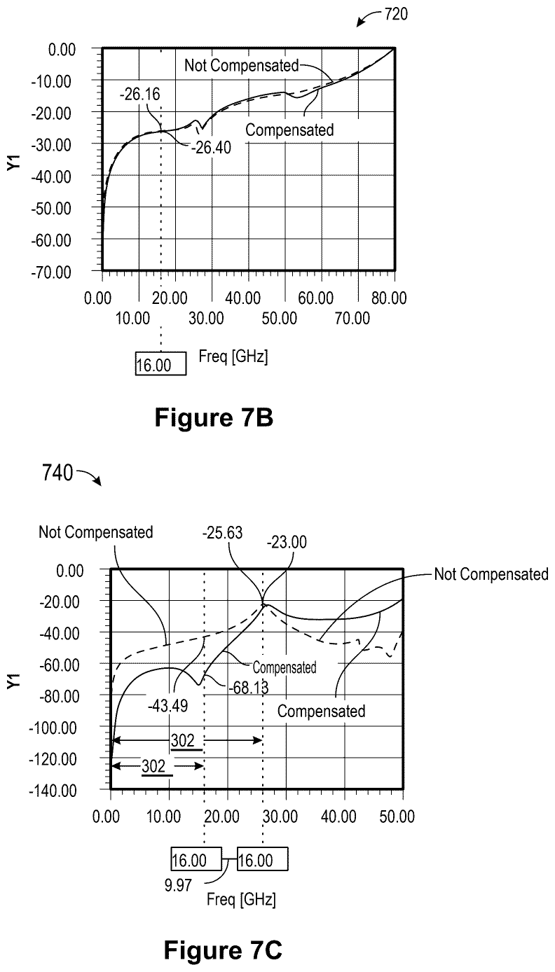

FIG. 7A is a graph 700 comparing example differential mode insertion losses (SDD21) associated with a compensated electronic device 100 and an uncompensated electronic device 200, in accordance with some embodiments. A differential mode insertion loss (SDD21) is a parameter used to indicate a signal quality loss of differential mode transmission. The differential mode insertion loss SDD21 is equal to −3 dB at a cut-off frequency. In this example, the differential mode insertion loss (SDD21) measures a ratio of the differential signal coming out of the signal traces 506A and 506B and the differential signal going into the signal pads 126A and 126B.

FIG. 7B is a graph 720 comparing example differential mode reflection losses (SDD11) associated with a compensated electronic device 100 and an uncompensated electronic device 200, in accordance with some embodiments. A differential mode reflection loss (SDD11) is a ratio of the differential signal coming out of an input signal port to the differential signal going into the input signal port. In this example, the differential mode reflection loss (SDD11) measures a ratio of the differential signal coming out of the signal pads 126A and 126B and the differential signal going into the signal pads 126A and 126B.

FIG. 7C is a graph 740 comparing example differential-to-common mode losses (SCD21) associated with a compensated electronic device 100 and an uncompensated electronic device 200, in accordance with some embodiments. A differential-to-common mode loss (SCD21) is a ratio of a ratio of a common-mode output voltage at an output port to a differential-mode input voltage at an input port. In this example, the differential-to-common mode losses (SCD21) measures a ratio of a common mode portion of the differential signal coming out of the signal traces 506A and 506B and a differential portion of the differential signal going into the signal pads 126A and 126B. In some embodiments, the differential-to-common mode losses (e.g., SCD21) quantifies a level on which a differential signal is converted into a common-mode signal as it passes through a device or interconnect. In some situations, when a first power wire 124 (e.g., for VSS or ground) is associated with a faster signal return than a second power bond wire 144 (e.g., for VDD), the differential signal has a higher value of the differential-to-common mode losses (SCD21), indicating an undesirable level of differential-to-common mode conversion.

Referring to FIGS. 7A and 7B, in some embodiments, the compensation structure 110 applied to a first power plane 120 of a first power supply does not compromise the cutoff frequency of the differential mode insertion loss (SDD21), nor does it create noticeable impact on the differential mode reflection loss (SDD11). In other words, the compensation structure 1110 does not impact performance of the differential signal carried by signal pads 126A and 126B, signal wires 108A and 108B, wire pads 106A and 106B, and signal traces 506A and 506B. Referring to FIG. 7C, the compensation structure 1110 reduces the differential-to-common mode losses (SCD21) in at least a first frequency range 302 (e.g., 0-26 GHz). The first frequency range 302 includes an operating bandwidth range 304 (e.g., 0-16 GHZ). In an example, the compensation structure 110 shown in FIG. 6A and its associated compensation circuit in FIG. 6B impact the differential mode insertion loss (SDD21), the differential mode reflection loss (SDD11), and the differential-to-common mode losses (SCD21) as follows:

TABLE 1
Comparison of performances an electronic devices
having a compensation structure and another electronic
device having no compensation structure

| Item (@ 16 GHz) | SDD 21 | SDD 11 | SCD 21 |
|---|---|---|---|
| No Compensation Structure | 0.21 dB | −26.90 dB | −46.74 dB |
| Having Compensation Structure | 0.20 dB | −26.97 dB | −60.81 dB |

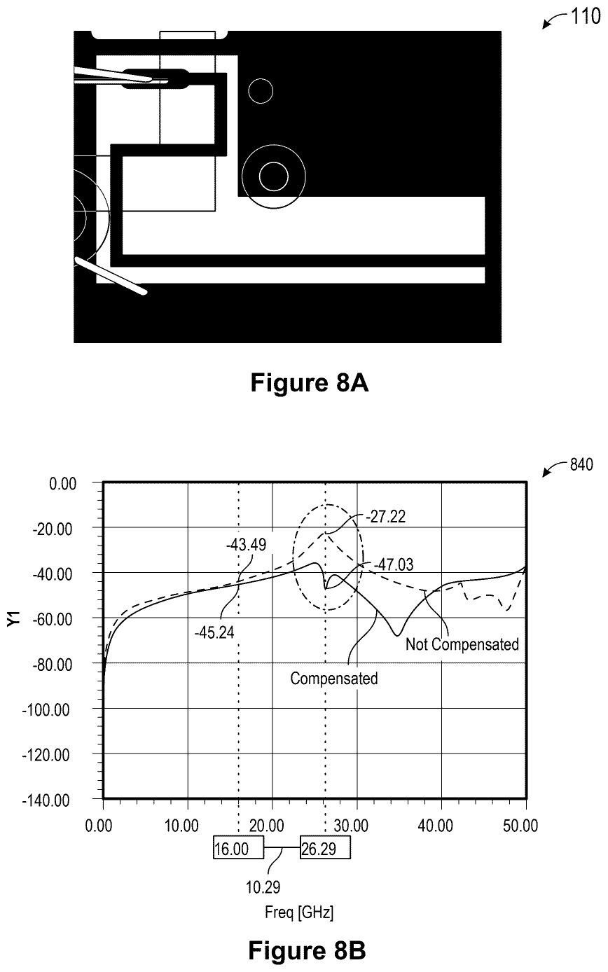

FIG. 8A is a top view of another example compensation structure 110 applied in an electronic device 100, in accordance with some embodiments, and FIG. 8B is a graph 840 comparing example differential-to-common mode losses (SCD21) associated with a compensated electronic device 100 using the compensation structure 110 shown in FIG. 8A and an uncompensated electronic device 200, in accordance with some embodiments. An electronic device (compensated or uncompensated) includes a device substrate 102 configured to support an electronic chip 104 and two wire pads 106A and 106B coupled on a surface of the device substrate 102, and the device substrate 102 includes a first power plane 120 and a second power plane 140. In an example, the first power plane 120 is a ground plane electrically coupled to a ground of the electronic device. Referring to FIG. 8A, in some embodiments, the first power plane 120 further includes a cutout opening 112 and a conductive contact path 114 starting from an edge of the cutout opening 112. The contact path 114 extends within the cutout opening 112, and terminates at a first power pad 122 located inside the cutout opening 112. The cutout opening 112 and the conductive contact path 114 form the compensation structure 110 of the first power plane 120. In some embodiments, the cutout opening 112 has a shape corresponding to one of a group of shapes consisting of a rectangular shape, a circular shape, a triangular shape, an “L” shape, and an “T” shape. In this example (FIG. 8), the cutout opening 112 has an “L” shape” that is flipped and rotated.

In an example, an AC common voltage is equal to 21.16 mV in an uncompensated electronic device 200. An AC common voltage is equal to 8.50 mV in an electronic device 100 having the compensation structure 110. The compensation structure 110 reduces an level of the AC common voltage of the differential signal transferred in the electronic device 100, thereby enhancing an associated differential-to-common mode losses (SCD21). In some embodiments, the conductive contact path 114 is configured to provide an operating bandwidth range in which the differential-to-common mode losses (SCD21) is improved. For example, the compensation structure 110 is applied to reduce the differential-to-common mode losses (SCD21) of the differential signal by 20 dB at 26 GHz.

FIG. 9A is a schematic view of an example compensation circuit 900 including a plurality of distributed parasitic components 910, in accordance with some embodiments. FIGS. 9B-9D are top views of three example compensation structures 110-1, 110-2, and 110-3 that are represented by respective compensation circuits, in accordance with some embodiments. In some embodiments, the compensation circuit 900 corresponds to a compensation structure 110, and is determined to be represented by a plurality of distributed parasitic components 910. Each component 910 includes an inductor 906 and a capacitor 902 that is arranged in parallel with the inductor 906. The inductor 906 may include a parasitic resistor 904, which is shown separately from the inductor 906. Further, in some embodiments, a mismatch is measured between an impedance measured at the first power pad 122 of the first power plane 120 and an impedance measured at the second power pad area 144 of the second power plane 140, and the plurality of distributed parasitic components 910 to control the mismatch (e.g., make it equal to zero or below a mismatch tolerance). In some embodiments, a differential-to-common mode losses (SCD21) of the differential signal is measured and applied to determine the compensation circuit 900.

In some embodiments, the first power plane 120 is electrically coupled to a ground, and the second power plane 140 is electrically coupled to a high power supply that is above the ground. Conversely, in some embodiments, the first power plane 120 is electrically coupled to a high power supply that is above the ground, and the second power plane 140 is electrically coupled to a ground. In some embodiments, the first power plane 120 is electrically coupled to a first power supply VSS is below a ground level, and the second power plane 140 is electrically coupled to a second power supply VDD that is above the ground level. Conversely, in some embodiments, the first power plane 120 is electrically coupled to a first power supply VDD is above a ground level, and the second power plane 140 is electrically coupled to a second power supply VSS that is below the ground level.

In some embodiments, each distributed parasitic component 910 corresponds to a respective rectangular segment 920 having a plurality of geometric characteristics (e.g., a respective width W, a respective length L, a position in the conductive contact path 114, and distances from edges of the cutout opening 112). The plurality of geometric characteristics of each rectangular segment 920 is configured to provide electrical properties of the distributed parasitic component 910. Respective rectangular segments 920 corresponding to the plurality of distributed parasitic components 910 are arranged to form the conductive contact path 114.

In some embodiments, a starting end on the conductive contact path 114 is disposed in a predefined pad location of the first power pad 122 on the device substrate 102. Edges of the cutout opening 112 is created on the first power plane 120 based on the conductive contact path (e.g., based on geometric characteristics of individual rectangular segments 920).

In some embodiments, the conductive contact path 114 includes a plurality of rectangular segments 920 each having a segment width W and a segment length L. Further, in some embodiments, the conductive contact path 114 has one or more characteristic frequencies. A number of segments, segment widths, and segment lengths of the plurality of rectangular segments 920 are determined based on the one or more characteristic frequencies. In some embodiments, the second power plane 140 includes a plurality of plane portions. For each respective rectangular segment 920 of the conductive contact path 114, the segment width and the segment length of the respective rectangular segment 920 are configured to match parasitic parameters of the respective rectangular segment 920 of the first power plane 120 to those of a respective one of the plurality of plane portions of the second power plane 140.

Referring to FIGS. 9B-9D, in some embodiments, the segment width is fixed for the plurality of rectangular segments 920, and the plurality of rectangular segments form a serpentine shape (FIGS. 9B and 9C), an “S” shape (FIG. 8A), or a spiral shape (FIG. 9D). Further, in some embodiments (FIG. 9A), the first power pad 122 sits in the cutout opening 112, and is electrically coupled to the first power plan only via the conductive contact path 114. Alternatively, in some embodiments (FIGS. 9B and 9C), the first power pad 122 is electrically coupled to an edge of the cutout opening 112 directly and via the conductive contact path 114.

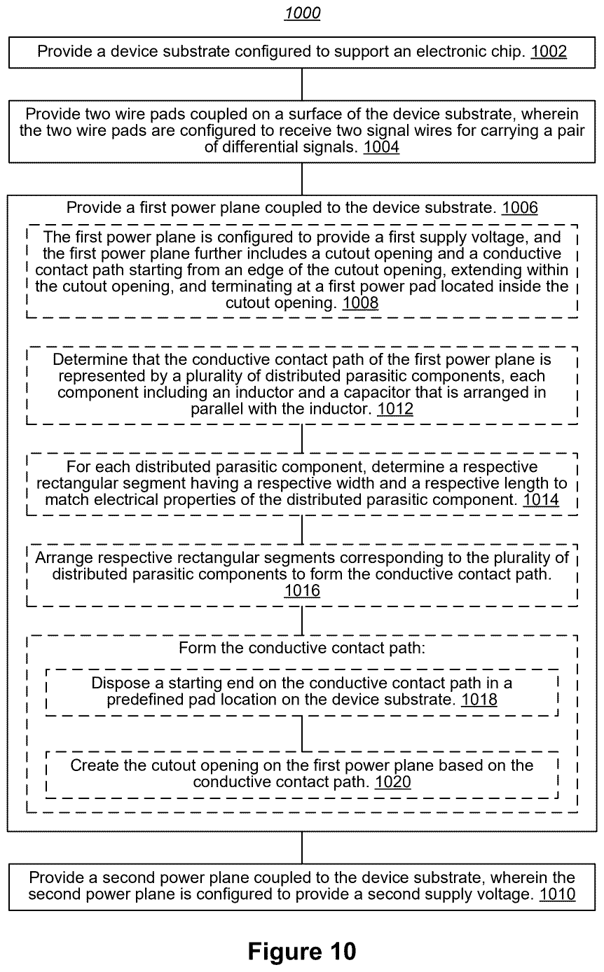

FIG. 10 is a flow diagram of an example method 1000 for providing an electronic device 100, in accordance with some embodiments. The method 1000 includes providing (operation 1002) a device substrate 102 configured to support an electronic chip 104, providing (operation 1004) two wire pads 106A and 106B coupled on a surface of the device substrate 102, providing (operation 1006) a first power plane 120 coupled to the device substrate 102, and providing (operation 1010) a second power plane 140 coupled to the device substrate 102 (FIG. 1). The two wire pads 106A and 106B are configured to receive two signal wires 108A and 108B for carrying a differential signal. The first power plane 120 is configured to provide a first supply voltage, and the first power plane 120 further includes (operation 1008) a cutout opening 112 and a conductive contact path 114 starting from an edge of the cutout opening 112, extending within the cutout opening 112, and terminating at a first power pad 122 located inside the cutout opening 112. The second power plane 140 is configured to provide a second supply voltage.

In some embodiments, providing the first power plane 120 further includes determining (operation 1012) that the conductive contact path 114 of the first power plane 120 is represented by a plurality of distributed parasitic components 910. Each component 910 includes an inductor and a capacitor 902 that is arranged in parallel with the inductor 906 (FIG. 9A). Providing the first power plane 120 further includes for each distributed parasitic component 910, determining (operation 1014) a respective rectangular segment 920 having a respective width and a respective length to match electrical properties of the distributed parasitic component 910 and arranging (operation 1016) respective rectangular segments 920 corresponding to the plurality of distributed parasitic components 910 to form the conductive contact path 114. Further, in some embodiments, providing the first power plane 120 further includes forming the conductive contact path 114 by disposing (operation 1018) a starting end on the conductive contact path 114 in a predefined pad location on the device substrate 102 and creating (operation 1020) the cutout opening 112 on the first power plane 120 based on the conductive contact path 114.

In some embodiments, the first power pad 122 is configured to receive a first power wire for carrying the first supply voltage. The second power plane 140 includes a second power pad area 142 configured to receive a second power wire 144 for carrying the second supply voltage. An impedance measured at the first power pad 122 of the first power plane 120 is configured to match an impedance measured at the second power pad area 142 of the second power plane 140.

In some embodiments, the method 1000 further includes providing the electronic chip 104 disposed on top of the device substrate 102. The electronic chip 104 is configured to generate the differential signal and output the differential signal via a pair of signal pads 126A and 126B, and the two signal wires 108A and 108B are configured to transfer the differential signal from the pair of signal pads 126A and 126B to the two wire pads 106A and 106B.

In some embodiments, the method 1000 further includes providing the electronic chip 104 disposed on top of the device substrate 102. The electronic chip 104 further includes two device power pads 128 and 148 electrically coupled to the first power plane 120 and the second power plane 140 using two distinct power wires 124 and 144, and the electronic chip 104 is configured to generate the differential signal with reference to the first supply voltage and the second supply voltage. The first supply voltage is lower than the second supply voltage.

In some embodiments, the first power plane 120 is electrically coupled to a ground.

In some embodiments, the first power plane 120 is exposed on the surface of the device substrate 102 jointly with the first power pad 122, the conductive contact path 114, and the two wire pads 106A and 106B.

In some embodiments, the first power plane 120 is embedded within the device substrate 102 jointly with the conductive contact path 114, and the first power pad 122 and the two wire pads 106A and 106B are exposed on the surface of the device substrate 102.

In some embodiments, the conductive contact path 114 includes a plurality of rectangular segments 920 each having a segment width and a segment length. Further, in some embodiments, the conductive contact path 114 has one or more characteristic frequencies, and a number of segments 920, segment widths, and segment lengths of plurality of rectangular segments 920 are determined based on the one or more characteristic frequencies. In some embodiments, the second power plane 140 includes a plurality of plane portions, and for each respective rectangular segment 920 of the conductive contact path 114, the segment width and the segment length are configured to match parasitic parameters of the respective rectangular segment 920 of the first power plane 120 to those of a respective one of the plurality of plane portions of the second power plane 140. In some embodiments, the segment width is fixed for the plurality of rectangular segments 920, and the plurality of rectangular segments 920 forms a serpentine shape (FIGS. 9B and 9C), an “S” shape (FIG. 8A), or a spiral shape (FIG. 9D).

In some embodiments, the device substrate 102 includes a printed circuit board.

In some embodiments, the first power pad 122 has a predefined location that is aligned with locations of the two wire pads 106A and 106B.

In some embodiments, the cutout opening 112 has a shape corresponding to one of a group of shapes consisting of a rectangular shape (FIGS. 9B-9D), a circular shape, a triangular shape, an “L” shape (FIG. 8A), and an “T” shape.

It should be understood that the particular order in which the operations in FIG. 10 have been described are merely exemplary and are not intended to indicate that the described order is the only order in which the operations could be performed. One of ordinary skill in the art would recognize various ways to reorder the operations described herein. It should be noted that details of systems, devices, and circuits described with respect to any of FIGS. 1-9 are also applicable in an analogous manner to the method 1000. For brevity, these details are not repeated here.

Certain embodiments are described herein as including logic or a number of components, modules, or mechanisms. A hardware module is tangible unit capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion embodied as executable instructions or code) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “some embodiments” or “an embodiment” means that a particular element, feature, structure, or characteristic described in connection with the embodiment is included in at least some embodiments. The phrase “in some embodiments” in various places in the specification is not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise. Upon reading this disclosure, those of skill in the art will appreciate still additional alternative structural and functional designs for a bi-directional scalable intra-panel interface disclosed herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope described.

What is claimed is:

1. An electronic device, comprising:
a device substrate configured to support an electronic chip;
two wire pads coupled on a surface of the device substrate, wherein the two wire pads are configured to receive two signal wires for carrying a differential signal;
a first power plane coupled to the device substrate, wherein the first power plane is configured to provide a first supply voltage, and the first power plane further includes a cutout opening and a conductive contact path starting from an edge of the cutout opening, extending within the cutout opening, and terminating at a first power pad located inside the cutout opening; and
a second power plane coupled to the device substrate, wherein the second power plane is configured to provide a second supply voltage.

2. The electronic device of claim 1, wherein:
the first power pad is configured to receive a first power wire for carrying the first supply voltage; and
the second power plane includes a second power pad area configured to receive a second power wire for carrying the second supply voltage;
wherein an impedance measured at the first power pad of the first power plane is configured to match an impedance measured at the second power pad area of the second power plane.

3. The electronic device of claim 1, further comprising:
the electronic chip disposed on top of the device substrate, wherein the electronic chip is configured to generate the differential signal and output the differential signal via a pair of signal pads, and the two signal wires are configured to transfer the differential signal from the pair of signal pads to the two wire pads.

4. The electronic device of claim 1, further comprising:
the electronic chip disposed on top of the device substrate, wherein the electronic chip further includes two device power pads that are electrically coupled to the first power plane and the second power plane using two distinct power wires, and the electronic chip is configured to generate the differential signal with reference to the first supply voltage and the second supply voltage, the first supply voltage being lower than the second supply voltage.

5. The electronic device of claim 1, wherein the first power plane is electrically coupled to a ground.

6. The electronic device of claim 1, wherein the first power plane is exposed on the surface of the device substrate jointly with the first power pad, the conductive contact path, and the two wire pads.

7. The electronic device of claim 1, wherein the first power plane is embedded within the device substrate jointly with the conductive contact path, and the first power pad and the two wire pads are exposed on the surface of the device substrate.

8. The electronic device of claim 1, wherein the conductive contact path includes a plurality of rectangular segments each having a segment width and a segment length.

9. The electronic device of claim 8, wherein the conductive contact path has one or more characteristic frequencies, and a number of segments, segment widths, and segment lengths of plurality of rectangular segments are determined based on the one or more characteristic frequencies.

10. The electronic device of claim 8, wherein the second power plane includes a plurality of plane portions, and for each respective rectangular segment of the conductive contact path, the segment width and the segment length are configured to match parasitic parameters of the respective rectangular segment of the first power plane to those of a respective one of the plurality of plane portions of the second power plane.

11. The electronic device of claim 8, wherein the segment width is fixed for the plurality of rectangular segments, and the plurality of rectangular segments forms a serpentine shape, an “S” shape, or a spiral shape.

12. The electronic device of claim 1, wherein the device substrate includes a printed circuit board.

13. The electronic device of claim 1, wherein the first power pad has a predefined location that is aligned with locations of the two wire pads.

14. The electronic device of claim 1, wherein the cutout opening has a shape corresponding to one of a group of shapes consisting of a rectangular shape, a circular shape, a triangular shape, an “L” shape, and an “T” shape.

15. An apparatus, comprising:
a device substrate configured to support an electronic chip;
two wire pads coupled on a surface of the device substrate, wherein the two wire pads configured to receive two signal wires for carrying a differential signal;
a first power plane coupled to the device substrate, wherein the first power plane is configured to provide a first supply voltage, and the first power plane further includes a cutout opening and a conductive contact path starting from an edge of the cutout opening, extending within the cutout opening, and terminating at a first power pad located inside the cutout opening; and
a second power plane coupled to the device substrate, wherein the second power plane is configured to provide a second supply voltage.

16. A method for providing an electronic device, comprising:
providing a device substrate configured to support an electronic chip;
providing two wire pads coupled on a surface of the device substrate, wherein the two wire pads are configured to receive two signal wires for carrying a differential signal;
providing a first power plane coupled to the device substrate, wherein the first power plane is configured to provide a first supply voltage, and the first power plane further includes a cutout opening and a conductive contact path starting from an edge of the cutout opening, extending within the cutout opening, and terminating at a first power pad located inside the cutout opening; and
providing a second power plane coupled to the device substrate, wherein the second power plane is configured to provide a second supply voltage.

17. The method of claim 16, providing the first power plane further comprising:
determining that the conductive contact path of the first power plane is represented by a plurality of distributed parasitic components, each component including an inductor and a capacitor that is arranged in parallel with the inductor;
for each distributed parasitic component, determining a respective rectangular segment having a respective width and a respective length to match electrical properties of the distributed parasitic component;
arranging respective rectangular segments corresponding to the plurality of distributed parasitic components to form the conductive contact path.

18. The method of claim 17, further comprising forming the conductive contact path by:
disposing a starting end on the conductive contact path in a predefined pad location on the device substrate; and
creating the cutout opening on the first power plane based on the conductive contact path.

19. The method of claim 16, wherein:
the first power pad is configured to receive a first power wire for carrying the first supply voltage; and
the second power plane includes a second power pad area configured to receive a second power wire for carrying the second supply voltage;
wherein an impedance measured at the first power pad of the first power plane is configured to match an impedance measured at the second power pad area of the second power plane.

20. The method of claim 16, further comprising:
the electronic chip disposed on top of the device substrate, wherein the electronic chip is configured to generate the differential signal and output the differential signal via a pair of signal pads, and the two signal wires are configured to transfer the differential signal from the pair of signal pads to the two wire pads.
